(19) United States
(12) Patent Application Publication
(10) Pub. No.: US 2015/0262683 A1
(43) Pub. Date: Sep. 17, 2015

(54) MEMORY DEVICE AND METHOD PROGRAMMING/READING MEMORY DEVICE

(71) Applicant: SAMSUNG ELECTRONICS CO., LTD., Suwon-si (KR)

(72) Inventors: Ji-Seung YOUN, Seoul (KR); Hwa-Seok OH, Yongin-Si (KR); Seok-Won AHN, Suwon-Si (KR); Young-Wook KIM, Hwaseong-Si (KR)

(21) Appl. No.: 14/637,879

(22) Filed: Mar. 4, 2015

(30) Foreign Application Priority Data
Mar. 11, 2014 (KR) 10-2014-0028271

(51) Int. Cl. G11C 16/10; G11C 16/26; G11C 16/08

(52) U.S. Cl. CPC G11C 16/10; G11C 16/08; G11C 16/26

(57) ABSTRACT

A method of programming a memory device includes generating a row selection signal according to a command type of a command received from a memory controller, loading data to page buffers corresponding to bit lines assigned by the column selection signal, and programming memory cells connected to a word line assigned by the row selection signal based on the data loaded to the page buffers. The column selection signal being generated to selectively jump a portion of the page buffers corresponding to the bit lines according to the command type.

### CROSS-REFERENCE TO RELATED APPLICATION

This application claims the benefit of Korean Patent Application No. 10-2014-0028271 filed on Mar. 11, 2014, the subject matter of which is hereby incorporated by reference.

### BACKGROUND

The inventive concept relates generally to methods of operating a memory device, and more particularly, to methods of programming and reading a memory device.

Nonvolatile memory devices are commonly employed as data storage media in a range of applications. Data is written to a nonvolatile memory device using a set of commands and corresponding functions collectively implementing a program operation. Similarly, data is retrieved from a nonvolatile memory device using another set of commands and corresponding functions collectively implementing a read operation. The number, arrangement, set-up, inter-operation and overall speed of execution for these commands and corresponding functions largely define the data access performance of the constituent nonvolatile memory device.

In the context of contemporary, nonvolatile memory systems configured to store two or more data bits per memory (so-called, “multi-level memory cells” or “MLC”), the number and efficiency of execution for commands implementing read and program operations becomes particularly important.

### SUMMARY

Embodiments of the inventive concept provide methods of programming and reading a memory device that generally reduce overhead related to the execution of various commands implementing the program operation and read operation.

According to an aspect of the inventive concept, a method of programming a memory device includes; generating a row selection signal corresponding to a row address and a column selection signal corresponding to a column address in a memory cell array portion based on a command type received by the memory device, loading data into page buffers corresponding to bit lines assigned by the column selection signal, and programming memory cells connected to a word line assigned by the row selection signal based on the data loaded into the page buffers, wherein the column selection signal is generated to selectively jump a portion of the page buffers according to the command type.

According to another aspect of the inventive concept, a method of reading a memory device includes; generating a row selection signal corresponding to a row address and a column selection signal corresponding to a column address in a memory cell array portion based on a type of a command received from a memory controller, loading data stored in memory cells of the memory array portion connected to a word line assigned by the row selection signal to page buffers, and reading the data loaded to the page buffers corresponding to bit lines assigned by the column selection signal, wherein the column selection signal is generated to selectively jump a portion of the page buffers according to a command type.

According to another aspect of the inventive concept, a memory device receiving a command of various type from a memory controller includes; a memory cell array portion, and a column decoder that receives a column address and generates a corresponding column selection signal in response to the command type, wherein the column selection signal is during read/write operation to select page buffers corresponding to bit lines, and if the command type is a first-type command, the column decoder generates a column selection signal that enables jumping of page buffers corresponding to bit lines included in a dummy column address section of the memory cell array portion.

### BRIEF DESCRIPTION OF THE DRAWINGS

Certain embodiments of the inventive concept are described hereafter with reference to the accompanying drawings in which:

FIG. 1 is a general block diagram illustrating a memory system according to an embodiment of the inventive concept;

FIG. 2 is a block diagram further illustrating in one example the memory device 100 of FIG. 1;

FIG. 3 is a block diagram further illustrating in one example the column decoder 142 of FIGS. 1 and 2;

FIG. 4 is an equivalent circuit for a first memory block (BLK1) of a memory cell array portion that may be included in the memory device of FIG. 2;

FIGS. 5 and 6 are schematic views respectively illustrating examples of a memory block including dummy cell layers that may be included in the memory device of FIG. 2;

FIG. 7 is a cross-sectional view illustrating a cell string that may be included in the first memory block of FIG. 4;

FIG. 8 is a schematic view illustrating one approach to column address assignment for bit lines of a memory cell array portion of a memory device according to an embodiment of the inventive concept;

FIG. 9, inclusive of FIGS. 9(a), 9(b), 9(c) and 9(d), illustrates various page layouts in which dummy column address sections are set according to certain embodiments of the inventive concept;

FIGS. 10, 11 and 12, inclusive of FIGS. 10(a) and 10(b), FIGS. 11(a) and 11(b) and FIGS. 12(a) and 12(b) respectively, illustrate various methods of loading data to be programmed into a page buffer circuit using first, second and third-type commands according to embodiments of the inventive concept;

FIGS. 13, 14 and 15, inclusive of FIGS. 13(a) and 13(b), FIGS. 14(a) and 14(b) and FIGS. 15(a) and 15(b) respectively, illustrate page layouts and data showing method of reading data from a page buffer circuit using first, second and third-type commands according to embodiments of the inventive concept;

FIG. 16, inclusive of FIGS. 16(a) and 16(b), illustrates page layouts showing a partial read operation according to embodiments of the inventive concept;

FIG. 17, inclusive of FIGS. 17(a), 17(b) and 17(c), illustrates page layouts showing a partial read operation of data having different sizes with an address padding approach according to an embodiment of the inventive concept;

FIG. 18, inclusive of FIGS. 18(a), 18(b) and 18(c), illustrates page layouts showing a partial read operation of data having different sizes with an address padding approach and execution of two commands according to an embodiment of the inventive concept;

FIG. 19, inclusive of FIGS. 19(a), 19(b) and 19(c), illustrates page layouts showing a partial read operation of data having different sizes with an address jump function according to an embodiment of the inventive concept;

FIG. 20 is a flowchart summarizing a method of programming a memory device according to an embodiment of the inventive concept;

FIG. 21 is a flowchart summarizing a method of reading a memory device according to an embodiment of the inventive concept;

FIG. 22 is a perspective view illustrating a memory device according to an embodiment of the inventive concept;

FIG. 23 is a block diagram illustrating a memory module according to an embodiment of the inventive concept;

FIG. 24 is a block diagram illustrating a computing system including a memory system according to an embodiment of the inventive concept;

FIG. 25 is a schematic view illustrating a memory card according to an embodiment of the inventive concept;

FIG. 26 is a schematic view illustrating a system of transmitting and receiving contents including a memory device according to an embodiment of the inventive concept; and

FIG. 27 is a schematic view illustrating a mobile terminal including a memory device according to an embodiment of the inventive concept.

### DETAILED DESCRIPTION OF EMBODIMENTS

Various embodiments of the inventive concept will now be described in some additional detail with reference to the accompanying drawings. The following embodiments are provided so that this disclosure will be thorough and complete and will fully convey the scope of the inventive concept to those skilled in the art. The inventive concept may be embodied in many different forms and should not be construed as being limited to only illustrated embodiments. Throughout the written description and drawings, like reference numbers and labels denote like of similar elements.

The terminology used herein is for the purpose of describing particular embodiments only and is not intended to limit the inventive concept. As used herein, the singular terms “a,” “an” and “the” are intended to include the plural forms as well, unless the context clearly indicates otherwise. It will be understood that the terms “comprises”, “comprising,”, “includes”, “including”, “have” and/or “having” when used herein, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of this specification and the relevant art and will not be interpreted in an idealized or overly formal sense unless expressly so defined herein.

Expressions such as “at least one of” when preceding a list of elements, modify the entire list of elements and do not modify the individual elements of the list.

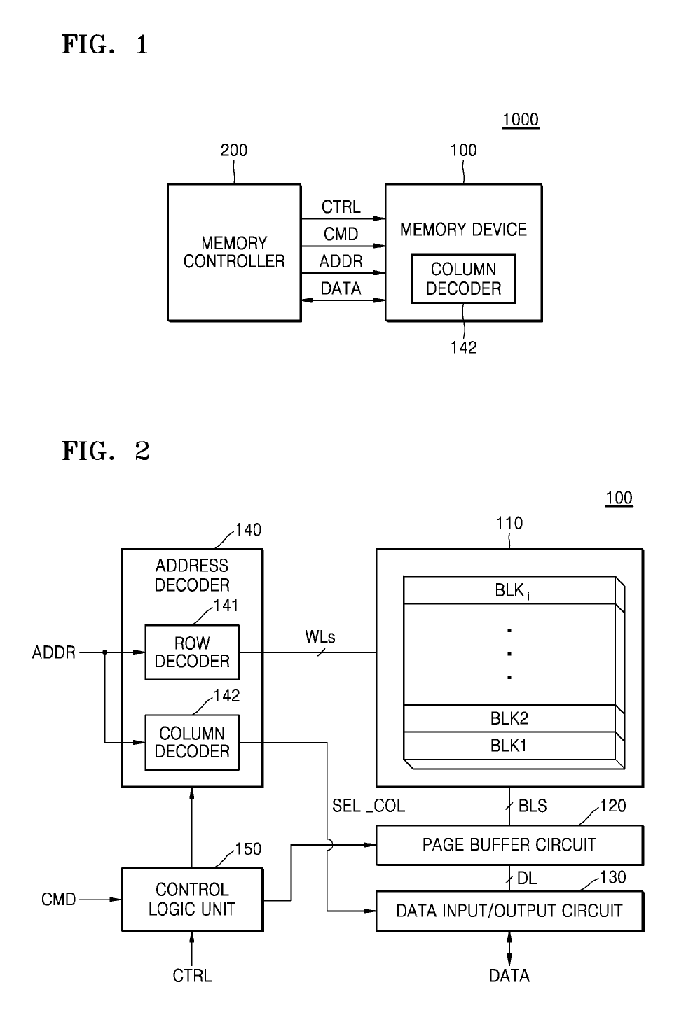

FIG. 1 is a block diagram illustrating a memory system 1000 according to an embodiment of the inventive concept. The memory system 1000 generally comprises a memory device 100 and a memory controller 200.

The memory controller 200 may be used to generate the command(s) CMD, address(es) ADDR, and/or control signal(s) CTRL necessary to the definition and execution of an erase operation, a write operation, or a read operation in the memory device 100. In this context, the memory controller 200 may generate different “types” of commands. Hereafter, the terms first-type command, second-type command, and third-type command will be used to illustrate this point in some detail.

The memory device 100 may be a nonvolatile memory device such as a flash memory device, a phase change random access memory (PRAM) device, or a magnetic random access memory (MRAM) device. Further, the memory device 100 may be applied to data storage media such as memory cards, universal serial bus (USB) memories, or solid state drives (SSDs) which are configured to include flash memory devices.

In its operation, the memory device 100 will execute various erase operation(s), write operation(s), and/or read operation(s) in response to command(s), address(es) and control signal(s) provided by the memory controller 200. Additionally, the memory device 100 will return read data to and receive write data from (collectively, DATA) the memory controller 200 via input/output (I/O) lines. Address(es) (individually or collectively, ADDR) may include a row address and a column address. A row address includes an address used to select a memory block of the memory cell array portion as well as an address used to select a page of the selected memory block. The column address includes an address used to select page buffer(s) corresponding to bit lines of the memory cell array portion.

The memory device 100 generally receives control signal(s) (individually or collectively, CTRL) via designated control lines. Typical control signals include; the command latch enablement signal, address latch enablement signal, chip enablement signal, write enablement signal, read enablement signal, etc.

The memory device 100 of FIG. 1 includes a column decoder 142. The column decoder 142 is used to receive a column address and generate a column selection signal in response to (or “based on”) the nature or type of received command. The column selection signal is a signal used to select page buffers corresponding to bit lines.

In certain embodiments of the inventive concept, if a “first-type command” is received by the memory device 100 from the memory controller 200, the column decoder 142 will generate a column selection signal that enables the jumping of page buffers corresponding to bit lines included in a dummy column address section. In this context, the dummy column address section will be predetermined or “initially set” before operation of the memory device 100 (e.g., upon power-up of the memory device 100, during post-production programming, etc.). In other embodiments of the inventive concept, if a “second-type command” is received by the memory device 100 from the memory controller 200, the column decoder 142 will generate a column selection signal that enables jumping page buffers corresponding to bit lines included in section(s) of the memory cell array other than the dummy column address section. And in still other embodiments of the inventive concept, if a “third-type command” is received by the memory device 100 from the memory controller 200, the column decoder 142 will generate a column selection signal that enables successive allocation of page buffers corresponding to bit lines included in the dummy column address section without jumping. In this context, first-type commands include a first-type write command and a first-type read command; the second-type command includes a second-type write command and a second-type read command; and the third-type command includes a third-type write command and a third-type read command.

FIG. 2 is a block diagram further illustrating the memory device 100 of FIG. 1.

Referring to FIG. 2, the memory device 100 comprises; a memory cell array portion 110, a page buffer circuit 120, a data input/output (I/O) circuit 130, an address decoder 140 and a control logic unit 150.

The memory cell array portion 110 may include a plurality of memory blocks BLK1 though BLKi. Each of the plurality of memory blocks BLK1 through BLKi may include a plurality of pages. Each page may include a plurality of memory cells. If the memory device 100 is a flash memory device, the memory device 100 may execute an erase operation in units of memory blocks and may execute a write operation or a read operation in units of pages.

The memory cell array portion 110 may be configured with a three-dimensional flash memory cell array structure or a two-dimensional flash memory cell array structure. FIG. 2 assumes the use of a three-dimensional vertical flash memory cell array structure.

The control logic unit 150 may be used to control the execution of erase operations, write operations, and read operations by the memory device 100 in response to various command(s) CMD, address(es) ADDR, and/or control signal(s) CTRL. The control logic unit 150 may also be used to generate a decoder control signal enabling various types of column address jumps according to a various types of commands.

Thus, if a first-type command is received by the control logic unit 150, the control logic unit 150 may generate a first decoder control signal (CTRL_DEC1) for jumping page buffers corresponding to bit lines included in the (initially set) dummy column address section, or if a second-type command is received by the control logic unit 150, the control logic unit 150 may generate a second decoder control signal (CTRL_DEC2) for jumping page buffers corresponding to bit lines included in a section other than the dummy column address section, or if a third-type command is received by the control logic unit 150, the control logic unit 150 may generate a third decoder control signal (CTRL_DEC3) that prevents page buffer jumping in relation to the dummy column address section.

In FIG. 2, the address decoder 140 comprises a row decoder 141 and a column decoder 142. The row decoder 141 receives a row address and generates a row selection signal that selects a memory block and page of the memory cell array portion 110. The column decoder 142 receives a column address and generates a column selection signal (SEL_COL) based on a decoder control signal and dummy column address section information provided by the control logic unit 150. The column selection signal may be used to select page buffers in the page buffer circuit 120.

In the context of this configuration, if a first-type command is received by the memory device 100, the column decoder 142 will generate a column selection signal for jumping page buffers corresponding to bit lines included in the dummy column address section based on the first decoder control signal (CTRL_DEC1); if a second-type command is received by the memory device 100, the column decoder 142 will generate a column selection signal for jumping page buffers corresponding to bit lines included in a section other than the dummy column address section based on the second decoder control signal (CTRL_DEC2), and if a third-type command is received by the memory device 100, the column decoder 142 will generate a column selection signal for successively allocating page buffers corresponding to bit lines included in the dummy column address section without jumping based on the third decoder control signal (CTRL_DEC3).

The page buffer circuit 120 may be selectively connected to the memory cell array portion 110 via bit lines BLS. The page buffer circuit 120 includes a plurality of page buffers, and in certain embodiments each page buffer will be connected to a single bit line BL, while in other embodiments each page buffer will be connected to two or more bit lines (BLs).

The data I/O circuit 130 may be internally connected to the page buffer circuit 120 via data lines DL and externally connected to the memory controller 200 via I/O lines. The data I/O circuit 130 is thus connected to receive the write data provided by the memory controller 200 during a program operation, and to provide read data received from the page buffer circuit 120 during a read operation.

The data I/O circuit 130 may be sued to select one or more page buffers in the page buffer circuit 120 in response to the column selection signal SEL_COL generated from the column decoder 142. The data I/O circuit 130 may load the write data received from the memory controller 200 to the page buffers corresponding to bit lines assigned by the column selection signal SEL_COL during the program operation, and may “read out” read data stored in the page buffers corresponding to bit lines assigned by the column selection signal SEL_COL to thereafter communicate the read data to the memory controller 200 during the read operation.

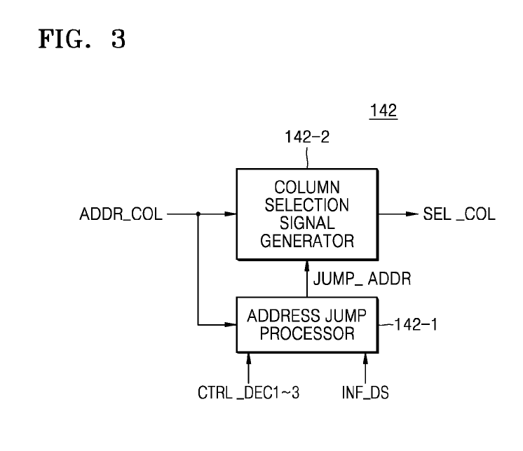

FIG. 3 is a block diagram illustrating in one example the column decoder 142 of FIGS. 1 and 2. Here, column decoder 142 comprises an address jump processor 142-1 and a column selection signal generator 142-2.

The address jump processor 142-1 receives a column address (ADDR_COL) to generate an address jump signal (JUMP_ADDR) based on one of the first, second or third decoder control signals (e.g., CTRL_DEC1, CTRL_DEC2 and CTRL_DEC3) and the dummy column address section information INF_DS provided by the control logic unit 150. The address jump processor 142-1 detects a column address to be decoded using the column address ADDR_COL as well as a data strobe signal. That is, if the column address ADDR_COL is counted using the data strobe signal, the address jump processor 142-1 may detect a column address to be decoded and may estimate whether the detected column address to be decoded reaches a start address of the dummy column address section. The data strobe signal may be used during the reading or writing of data, and may be provided by the control logic unit 150 of the memory device 100 or the memory controller 200 to the address jump processor 142-1.

If the first decoder control signal CTRL_DEC1 is received by the address jump processor 142-1, the address jump processor 142-1 will generate the address jump signal (JUMP_ADDR) instructing the column selection signal generator 142-2 to jump the dummy column address section. If the second decoder control signal CTRL_DEC2 is received by the address jump processor 142-1, the address jump processor 142-1 will generate the address jump signal instructing the column selection signal generator 142-2 to jump address section(s) other than the dummy column address section. And if the third decoder control signal CTRL_DEC3 is received by the address jump processor 142-1, no address jump signal will be generated by the address jump processor 142-1.

The column selection signal generator 142-2 receives the column address ADDR_COL and generates the column selection signal SEL_COL allocating page buffers according to the address jump signal JUMP_ADDR provided by the address jump processor 142-1. If no address jump signal is generated by the address jump processor 142-1, the column selection signal generator 142-2 will generate a column selection signal that sequentially allocates page buffers corresponding to the column address based on the size of data being loaded to the page buffer circuit 120. However, if the address jump signal is provided by the column selection signal generator 142-2, the column selection signal generator 142-2 may execute an “address jump operation” that essentially assigns a column address consistent with the address jump signal and thereby generates a column selection signal sequentially allocating page buffers from the page buffer corresponding to the column address instructed by the address jump signal after the address jump operation terminates.

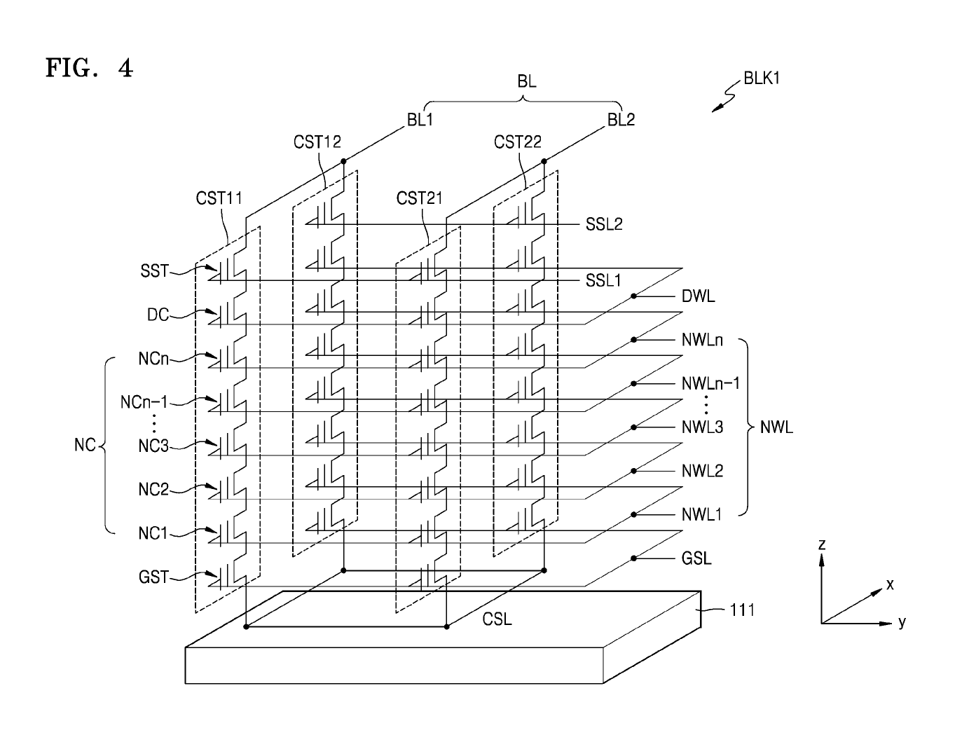

FIG. 4 is an equivalent circuit illustrating for a first memory block BLK1 of the memory cell array portion 110 that may be included in the memory device 100 of FIG. 2.

Referring to FIG. 4, the first memory block BLK1 includes a substrate 111, a plurality of cell strings CST, a dummy word line DWL, normal word lines NWL, bit lines BL, a ground selection line GSL and a common source line CSL. The number of the cell strings CST, the word lines WL and the bit lines BL included in the first memory block BLK1 mentioned hereinafter will be described in specific numbers for the purpose of ease and convenience in explanation. However, the inventive concept is not limited thereto. That is, the number of the cell strings CST, the word lines WL and the bit lines BL included in each of the memory blocks BLK1 though BLKi may be different according to the embodiments. Moreover, the number of normal cells included in each cell string CST may also be different according to the embodiments. In some embodiments, no dummy word line DWL is disposed in each of the memory blocks BLK1 through BLKi. That is, in some embodiments, the dummy word line DWL in FIG. 4 may be regarded as one of the normal word lines NWL.

The cell strings CST may be coupled between the bit lines BL and the common source line CSL. Each of the cell strings CST may extend in a vertical direction Z which is perpendicular to a surface of the substrate 111. Each of the cell strings CST may include a string selection transistor SST, a dummy cell DC, a plurality of normal cells NC, and a ground selection transistor GST which are connected in series between one of the bit lines BL and the common source line CSL. For example, a cell string CST11 may include a string selection transistor SST, a dummy cell DC, normal cells NC1 through NCn, and a ground selection transistor GST which are connected in series between a bit line BL1 and the common source line CSL.

The string selection transistors SST may be connected to a string selection line SSL extending in a column direction Y and an operation of the string selection transistors SST may be controlled by a signal applied to the string selection line SSL. The ground selection transistors GST may be connected to a ground selection line GSL extending in the column direction Y and a row direction X and an operation of the ground selection transistors GST may be controlled by a signal applied to the ground selection line GSL. For example, the string selection transistor SST of the cell string CST11 may be connected to a string selection line SSL1 and an operation of the string selection transistor SST of the cell string CST11 may be controlled by a signal applied to the string selection line SSL1, and the string selection transistor SST of the cell string CST12 may be connected to a string selection line SSL2 and an operation of the string selection transistor SST of the cell string CST12 may be controlled by a signal applied to the string selection line SSL2. In addition, the ground selection transistors GST of the cell strings CST11, CST12, CST21 and CST22 may be connected to the ground selection line GSL and operations of the ground selection transistors GST may be controlled by a signal applied to the ground selection line GSL.

The dummy cells DC may be connected to the dummy word line DWL extending in the row direction X and the column direction Y, and operations of the dummy cells DC may be controlled by a signal applied to the dummy word line DWL. Similarly, the normal cells NC may be connected to the normal word lines NWL extending in the row direction X and the column direction Y, and operations of the normal cells NC may be controlled by signals applied to the normal word lines NWL. For example, all of the dummy cells DC of the cell strings CST11, CST12, CST21 and CST22 may be connected to the shared dummy word line DWL. The dummy cells DC may exist to improve characteristics of the cell strings CST. For example, the dummy cells DC may alleviate the influence of degradation of the string selection transistors SST on the cell strings CST or may prevent the cell strings CST from being degraded due to a difference between voltages applied to the string selection transistors SST and the normal cells NC while the normal cells NC of the cell strings CST operate.

Data may be written or stored in the normal cells NC1 through NCn. First normal cells NC1 of the cell strings CST11, CST12, CST21 and CST22 may be connected to and controlled by a shared first normal word line NWL1, and second normal cells NC2 of the cell strings CST11, CST12, CST21 and CST22 may be connected to and controlled by a shared second normal word line NWL2. Similarly, N^{th} normal cells NCn of the cell strings CST11, CST12, CST21 and CST22 may be connected to and controlled by a shared N^{th} normal word line NWLn.

Each of the bit lines BL may be electrically connected to the plurality of cell strings CST which are arrayed in the row direction X. For example, the cell strings CST11 and CST12 arrayed in a first row may be electrically connected to the bit line BL1, and the cell strings CST21 and CST22 arrayed in a second row may be electrically connected to the bit line BL2. In some embodiments, the number of the bit lines BL may be greater than that of the bit lines BL illustrated in FIG. 4 and the number of the cell strings CST may also be greater than that of the cell strings CST illustrated in FIG. 4.

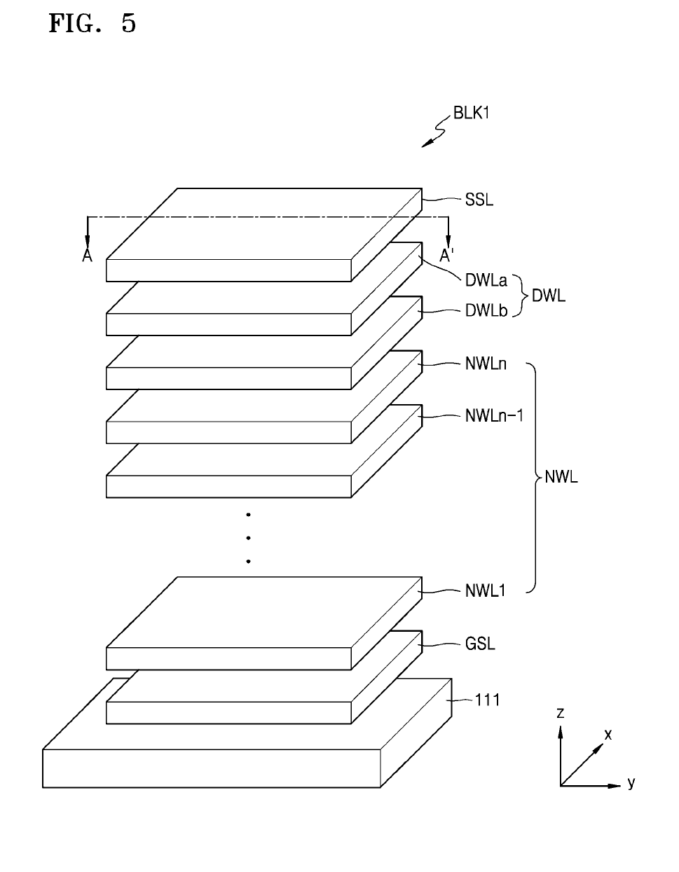

Although FIG. 4 illustrates an example in which each of the cell strings CST includes only one dummy cell DC, but the inventive concept is not limited thereto. Referring to FIG. 5, another example of the first memory block BLK1 is shown wherein a ground selection line GSL, normal word lines NWL, dummy word lines DWL and a string selection line SSL may be sequentially stacked in a vertical direction Z on the substrate 111. The ground selection line GSL, the normal word lines NWL, the dummy word lines DWL and the string selection line SSL may be connected to the ground selection transistors GST, the normal cells NC, the dummy cells DC, and the string selection transistors SST, respectively. The ground selection transistors GST, normal cells NC, dummy cells DC and string selection transistors SST are not shown in FIG. 5 for the sake of clarity. As illustrated in FIG. 5, the dummy word lines DWL may include two layers DWLa and DWLb adjacent to the string selection line SSL.

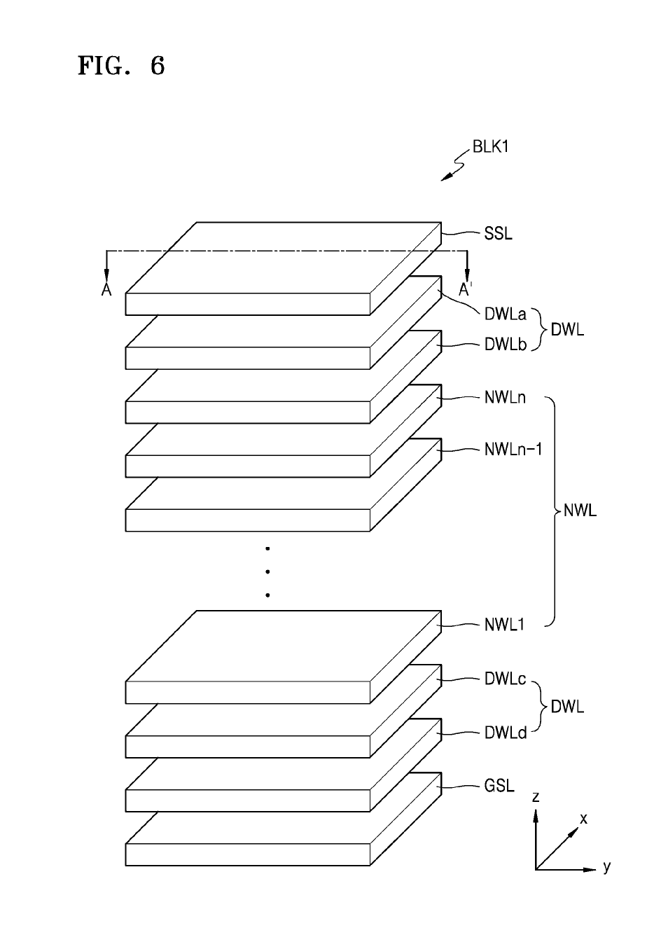

Referring to FIG. 6, another example of the first memory block BLK1 is shown wherein the dummy word lines DWL include two layers DWLa and DWLb adjacent to the string selection line SSL and two layers DWLc and DWLd adjacent to the ground selection line GSL. Alternatively, the dummy word lines DWL may be realized to include a single dummy line adjacent to the string selection line SSL and another single dummy line adjacent to the ground selection line GSL. The dummy cells DC or the layers illustrated by the dummy word lines DWL may reduce the influence of voltage signals applied to the ground selection line GSL, the normal word lines NWL, the dummy word lines DWL and the string selection line SSL on the cell strings while the memory device 100 operates.

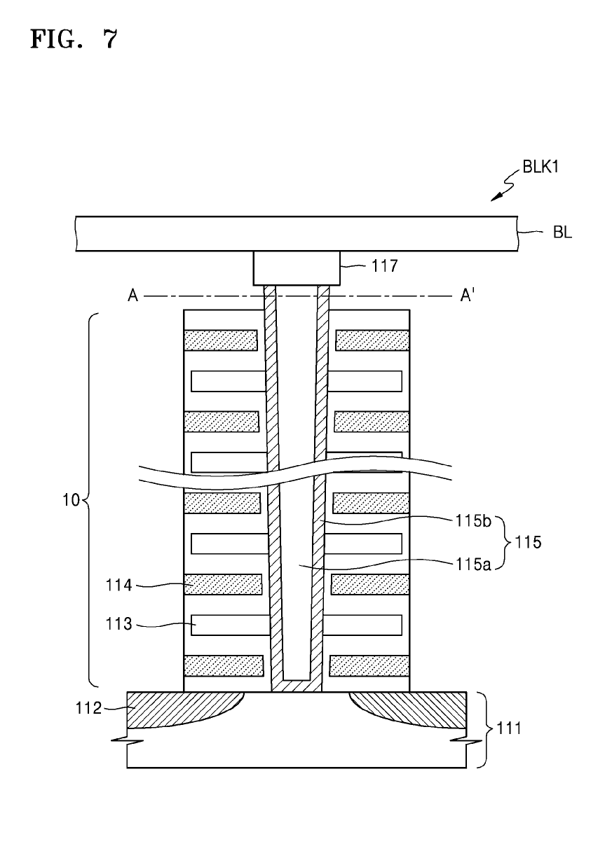

FIG. 7 is a cross-sectional view taken along a line A-A′ of FIG. 5 (or analogously FIG. 6). Referring to FIG. 7, a pair of wells 112 may be disposed in a substrate 111 to be spaced apart from each other. The substrate 111 may have a first conductivity type, and the pair of wells 112 may have a second conductivity type different from the first conductivity type. For example, the first conductivity type may be a P-type and the second conductivity type may be an N-type. Insulation patterns 113 and conductive patterns 114 may be alternately stacked on the substrate 111 between the pair of wells 112 to constitute a stack structure 10. The insulation patterns 113 may include a silicon oxide material, and the conductive patterns 114 may include a polysilicon material. The conductive patterns 114 may correspond to gates of the ground selection transistors GST, the normal cells NC, the dummy cells DC and the string selection transistors SST which are described above.

A channel structure 115 may be disposed to penetrate the stack structure 10 including the insulation patterns 113 and the conductive patterns 114. The channel structure 115 may connect the substrate 111 to a contact plug 117 that is disposed on the stack structure 10 to act as a drain of a cell string. The channel structure 115 may include a pillar 115a and a channel layer 115b surrounding the pillar 115a. The pillar 115a may include an insulation material.

As described above, the string selection transistors SST, the dummy cells DC, the normal cells NC and the ground selection transistors GST included in each of the cell strings CST may share the same channel layer. As illustrated in FIG. 7, the channel structure 115 may extend in the vertical direction Z which is perpendicular to the substrate 111. The channel structure 115 may have a channel last structure, for example, a bit-cost scalable (BiCS) structure that the channel structure 115 is formed after formation of the conductive patterns 114. Alternatively, the channel structure 115 may have a channel first structure, for example, a terabit cell array transistor (TCAT) structure that the conductive patterns 114 are formed after formation of the channel structure 115.

Referring back to FIG. 2, the row decoder 141 may be used to receive a row address to generate a row selection signal for selecting a word line in a memory block corresponding to the row address. For example, if the memory block corresponding to the row address is the first memory block BLK1, one of the word lines included in the first memory block BLK1 of FIG. 4 may be selected to execute a program operation or a read operation. The selected word line may be one of the normal word lines NWL and the dummy word line DWL. If the first memory block BLK1 is designed not to include the dummy word line DWL, the selected word line may be one of the normal word lines NWL.

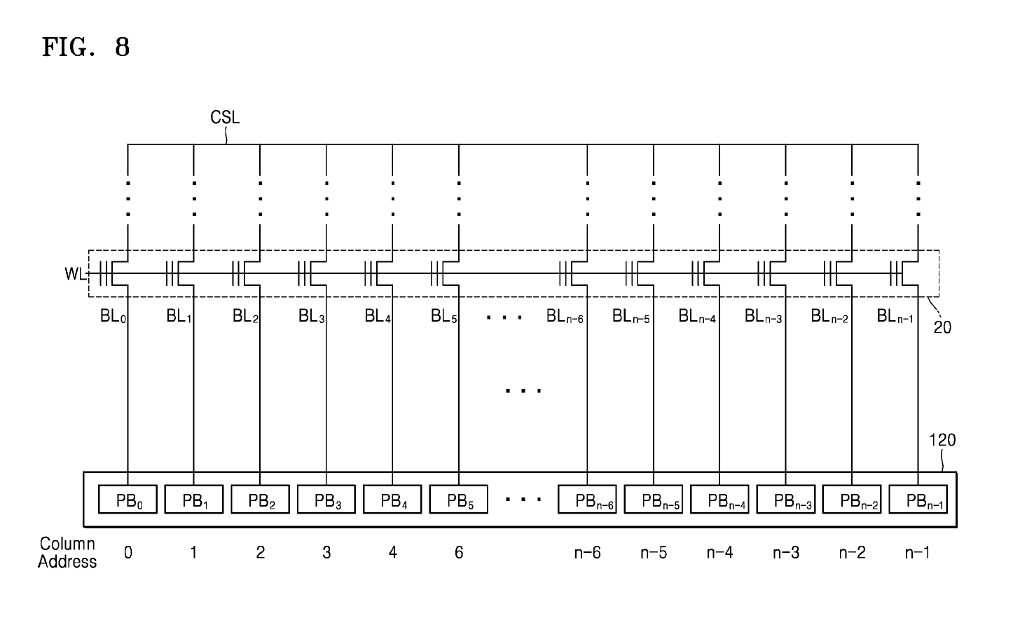

FIG. 8 is a schematic view illustrating in one example a column address assignment for a plurality of bit lines of the memory cell array portion 110 of the memory device 100 according to an embodiment of the inventive concept.

Referring to FIG. 8, each page buffer PB₀ through PBₙ₋₁ is shown as being respectively connected to one of the bit line BL₀ through or BLₙ₋₁ in the memory cell array portion 110 of FIG. 2. Thus, a selected page 20 will include ‘N’ memory cells, where “N” is a natural number greater than one. Each memory cell may be selectively connected to one of the page buffer PB₀ through PBₙ₋₁ in the page buffer circuit 120 via a corresponding bit line BL₀ through BLₙ₋₁. In such a case, column addresses corresponding to “0” through “N−1” may be sequentially assigned to the N-number of bit lines BL₀ through BLₙ₋₁ and the page buffers PB₀ through PBₙ₋₁.

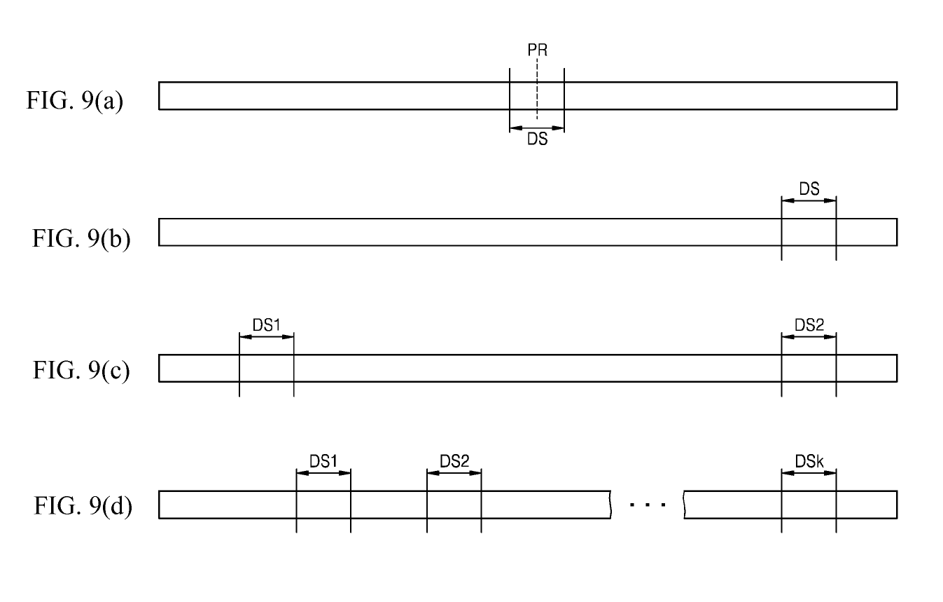

FIG. 9 illustrates various page layouts in which dummy column address sections are set according to certain embodiments of the inventive concept.

The dummy column address sections of the memory device may be set to have initial values. Each of FIG. 9(a) and FIG. 9(b) illustrates a page in which a single dummy column address section is set. Referring to FIG. 9(a), the single dummy column address section DS may be set at a column address corresponding to a half size of the page. This may correspond to an example in which the dummy column address section DS is set to support a partial read function which is described later. FIG. 9(b) illustrates an example in which the single dummy column address section DS is set at a random column address in the page.

FIG. 9(c) illustrates a page in which two dummy column address sections DS1 and DS2 are set, and FIG. 9(d) illustrates a page in which three or more dummy column address sections DS1˜DSk are set, where “k” is a natural number at least equal to three.

In certain embodiments of the inventive concept, dummy data may be written or stored in the dummy column address sections set according to the pages illustrated in FIGS. 9(a), 9(b), 9(c) and 9(d). Alternatively, specific data such as security information or error check information may be written or stored in the dummy column address sections set according to the pages illustrated in FIGS. 9(a), 9(b), 9(c) and 9(d).

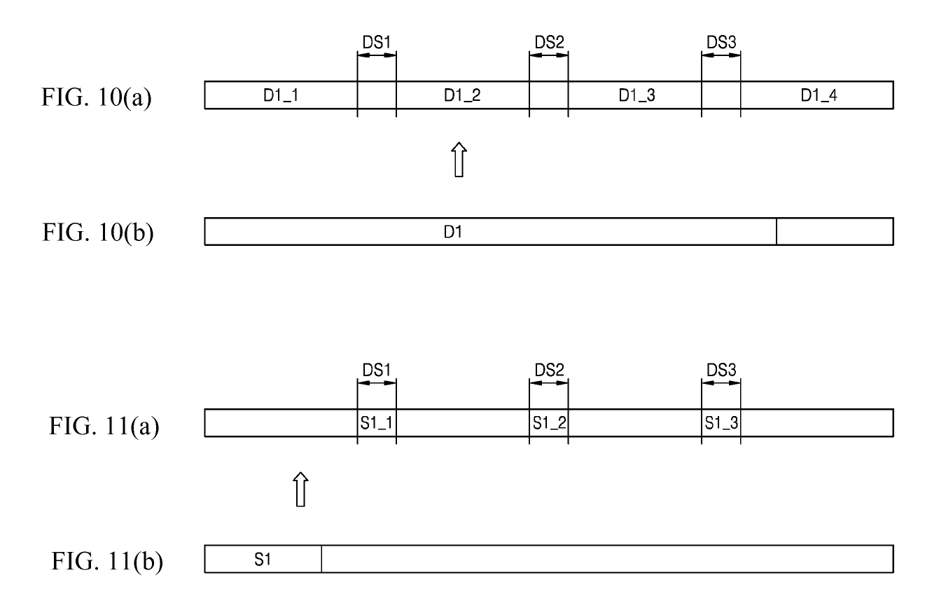

A program operation or read operation may be executed by the memory device 100 of FIG. 2 according to a first, second or third-type command as will described hereinafter in some additional detail with respect to FIGS. 10, 11, 12, 13, 14 and 15.

That is, FIGS. 10, 11, 12, 13, 14 and 15 respectively illustrate examples in which three (3) dummy column address sections DS1, DS2 and DS3 are set in a single page. Those skilled in the art recognize that this is merely an arbitrary teaching example and that the scope of the inventive concept is not limited thereto. For example, in certain other embodiments of the inventive concept, a single dummy column address section, or two (2) dummy column address sections may be set in a single page.

FIG. 10 illustrates a page layout and data showing a method of loading the data into the page buffer circuit 120 using a first-type command according to embodiments of the inventive concept.

If a first-type write command and an address are received by the memory device 100 together with the data D1 of FIG. 10(b), the control logic unit 150 may generate the first decoder control signal CTRL_DEC1.

The row decoder 141 may generate a row selection signal for selecting a memory block and a page of the memory cell array portion 110. The column decoder 142 may generate a column selection signal for jumping page buffers corresponding to bit lines included in the dummy column address sections DS1, DS2 and DS3 based on the first decoder control signal CTRL_DEC1.

Accordingly, the data D1—shown in FIG. 10(b)—received by the data I/O circuit 130 may be loaded to the page buffers of the page buffer circuit 120 to provide the page layout illustrated in FIG. 10(a). That is, the data D1 may be divided into four data D1_1, D1_2, D1_3 and D1_4, and the four data D1_1, D1_2, D1_3 and D1_4 may be loaded into four separate sections of the page other than the dummy column address sections DS1, DS2 and DS3.

The memory cells connected to the word line of the memory cell array portion 110 selected by the row selection signal may be programmed based on the data—shown in FIG. 10 (a)—loaded into the page buffers of the page buffer circuit 120.

FIG. 11 illustrates a page layout and data showing a method of loading the data into the page buffer circuit 120 using a second-type command according to some embodiments of the inventive concept.

If a second-type write command and an address are received by the memory device 100 together with the data S1 of FIG. 11(b), the control logic unit 150 may generate the second decoder control signal CTRL_DEC2. The data S1 may be specific data. For example, the data S1 may include security information or error check information.

The row decoder 141 may generate a row selection signal for selecting a memory block and a page of the memory cell array portion 110. The column decoder 142 may generate a column selection signal for jumping page buffers corresponding to bit lines included in a section other than the dummy column address sections DS1, DS 2 and DS3 based on the second decoder control signal CTRL_DEC2.

Accordingly, the data S1—shown in FIG. 11(b)—received by the data I/O circuit 130 may be loaded into the page buffer circuit 120 to provide the page layout illustrated in FIG. 11(a). That is, the data S1 may be divided into three data S1_1, S1_2 and S1_3, and the three data S1_1, S1_2 and S1_3 may be loaded into page buffers corresponding to the dummy column address sections DS1, DS2 and DS3.

The memory cells connected to the word line of the memory cell array portion 110 selected by the row selection signal may be programmed based on the data shown in FIG. 11(a) loaded into the page buffer circuit 120.

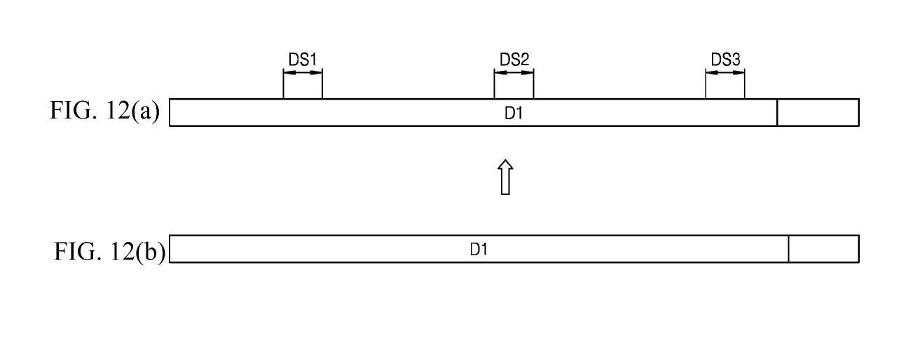

FIG. 12 illustrates a page layout and data showing a method of loading the data into the page buffer circuit 120 using a third-type command according to some embodiments of the inventive concept.

If a third-type write command and an address are received by the memory device 100 together with the data D1 of FIG. 12(b), the control logic unit 150 may generate the third decoder control signal CTRL_DEC3.

The row decoder 141 generates a row selection signal selecting a memory block and page of the memory cell array portion 110. The column decoder 142 generates a column selection signal successively allocating page buffers corresponding to bit lines without address jumping based on the third decoder control signal CTRL_DEC3.

Accordingly, the data D1—shown in FIG. 12(b)—received by the data I/O circuit 130 may be loaded into the page buffer circuit 120 to provide the page layout illustrated in FIG. 12(a). That is, the data D1 may be loaded into the page buffer circuit 120 including the dummy column address sections DS1, DS2 and DS3 without address jumping.

The memory cells connected to the word line of the memory cell array portion 110 selected by the row selection signal may be programmed based on the data of FIG. 12(a) loaded into the page buffer circuit 120.

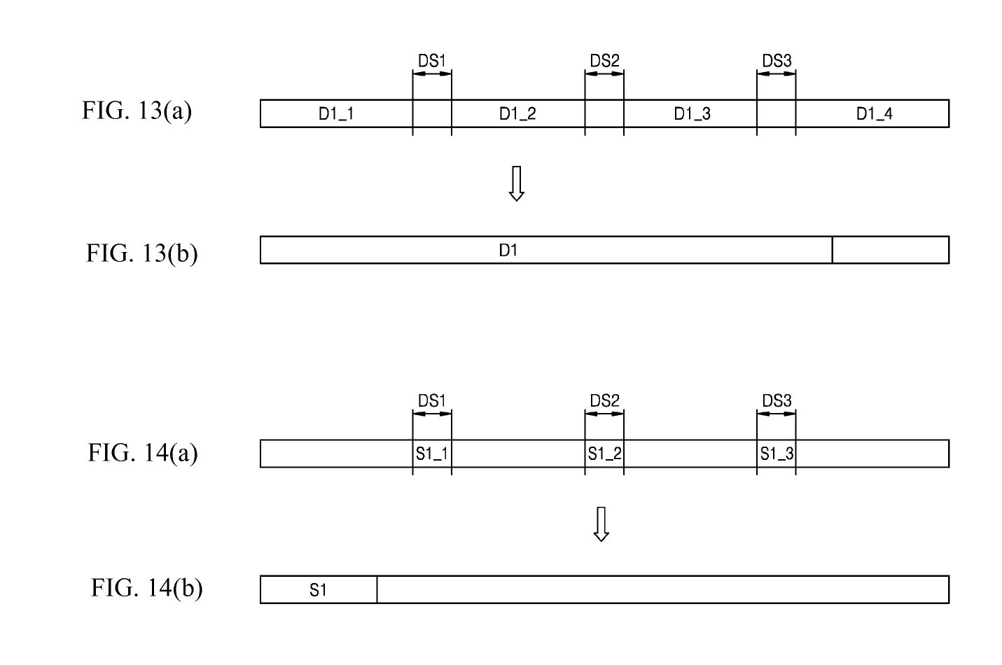

FIG. 13 illustrates a page layout and data showing a method of reading out the data from the page buffer circuit 120 using a first-type command according to embodiments of the inventive concept.

If a first-type read command and corresponding address are received by the memory device 100, the control logic unit 150 will generate the first decoder control signal CTRL_DEC1.

The row decoder 141 generates a row selection signal selecting a memory block and page of the memory cell array portion 110. Data stored in memory cells connected to a word line assigned by the row selection signal may be loaded into the page buffer circuit 120. For example, if the word line assigned by the row selection signal corresponds to the page programmed by the first-type write command, data D1_1, D1_2, D1_3 and D1_4 having the page layout of FIG. 13(a) may be loaded into the page buffer circuit 120 during a read operation.

The column decoder 142 generates a column selection signal for jumping page buffers corresponding to bit lines included in the dummy column address sections DS1, DS2 and DS3 based on the first decoder control signal CTRL_DEC1.

The data I/O circuit 130 may read out the data stored in the page buffers corresponding to the bit lines assigned by the column selection signal and may output the data to the memory controller 200. Accordingly, the data D1_1, D1_2, D1_3 and D1_4 in the page buffers corresponding to sections other than the dummy column address sections DS1˜DS3 may be read out to constitute data D1 illustrated in FIG. 13(b), and the data D1 may thereafter be communicated to the memory controller 200.

FIG. 14 illustrates a page layout and data showing a method of reading out the data from the page buffer circuit 120 using a second-type command according to embodiments of the inventive concept.

If a second-type read command and corresponding address are received by the memory device 100, the control logic unit 150 will generate the second decoder control signal CTRL_DEC2.

The row decoder 141 generates a row selection signal selecting a memory block and page of the memory cell array portion 110. Data stored in memory cells connected to a word line assigned by the row selection signal may be loaded into the page buffer circuit 120. For example, if the word line assigned by the row selection signal corresponds to the page programmed by the second-type write command, data S1_1, S1_2 and S1_3 having the page layout of FIG. 14(a) may be loaded into the page buffer circuit 120 during a read operation.

The column decoder 142 will generate a column selection signal for jumping page buffers corresponding to bit lines included in section(s) other than the dummy column address sections DS1, DS2 and DS3 based on the second decoder control signal CTRL_DEC2.

The data I/O circuit 130 may be used to read the data stored in the page buffers corresponding to the bit lines assigned by the column selection signal, and may thereafter communicate the data to the memory controller 200. Accordingly, the data S1_1, S1_2, and S1_3 in the page buffers corresponding to the dummy column address sections DS1, DS2 and DS3 may be read to constitute data S1 illustrated in FIG. 14(b), and the data S1 may thereafter be communicated to the memory controller 200.

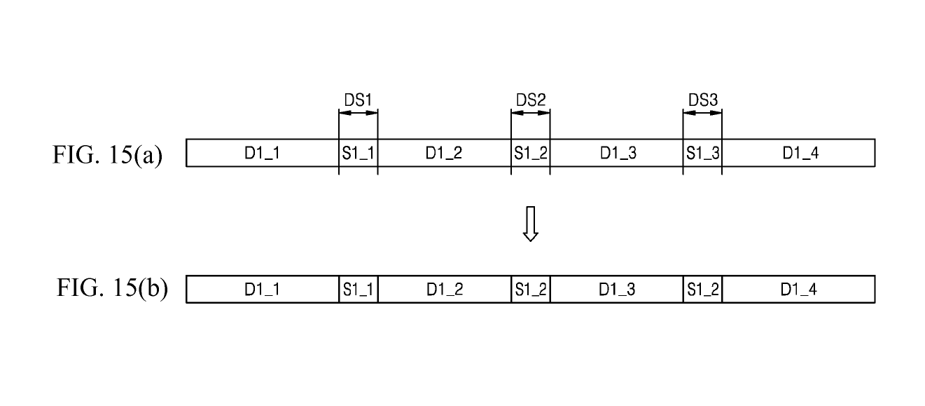

FIG. 15 illustrates a page layout and data showing a method of reading out the data from the page buffer circuit 120 using a third-type command according to embodiments of the inventive concept.

If a third-type read command and a corresponding address are received by the memory device 100, the control logic unit 150 will generate the third decoder control signal CTRL_DEC3.

The row decoder 141 generates a row selection signal selecting a memory block and page of the memory cell array portion 110. Data stored in memory cells connected to a word line assigned by the row selection signal may be loaded into the page buffer circuit 120. For example, if the word line assigned by the row selection signal corresponds to the page programmed by the third-type write command, data having the page layout of FIG. 15(a) may be loaded into the page buffer circuit 120 during a read operation.

That is, the example of FIG. 15(a) illustrates a page layout in which data S1_1, S1_2 and S1_3 are stored in the dummy column address sections DS1, DS2 and DS3 and data D1_1, D1_2, D1_3 and D1_4 are stored in sections other than the dummy column address sections DS1, DS2 and DS3.

The column decoder 142 may generate a column selection signal for successively allocating page buffers corresponding to bit lines without any column address jump processes based on the third decoder control signal CTRL_DEC3.

The data I/O circuit 130 may read out the data stored in the page buffers corresponding to the bit lines assigned by the column selection signal and may output the data to the memory controller 200. Accordingly, the data in all of the page buffers may be read to constitute data D1 and S1 illustrated in FIG. 15(b), and the data D1 and S1 may thereafter be communicated to the memory controller 200.

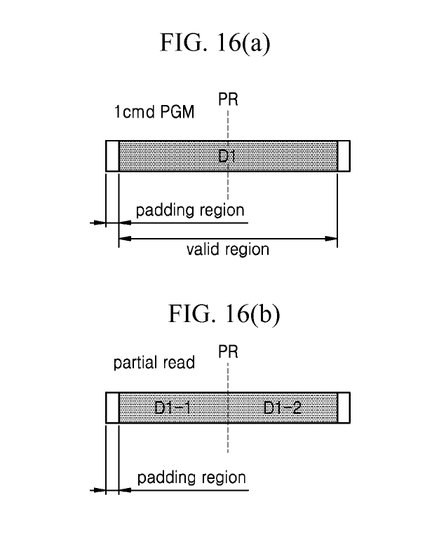

FIG. 16 illustrates page layouts showing a partial read operation with an address padding approach consistent with certain embodiments of the inventive concept.

If a dummy padding approach is applied to a page to define a left padding region and a right padding region having the same size at both ends of the page and a program operation is executed to store data D1 in the page, as illustrated in FIG. 16(a), a first half of the data D1 may be loaded into a left section of the page and a second half of the data D1 may be loaded into a right section of the page. The left section and the right section of the page may be divided by a partial read reference boundary PR located at a central region of the page. The legend “1cmd PGM” shown in FIG. 16(a) denotes a program operation performed by execution of a single command. If the page has a memory size of 8 Kbytes, 4 Kbyte data D1_1 may be loaded in the left section of the page and the remaining 4 Kbyte data D1_2 may be loaded in the right section of the page.

Accordingly, as illustrated in FIG. 16(b), the memory device 100 may support a partial read function that partially reads data having half the size of the page using the partial read reference boundary PR.

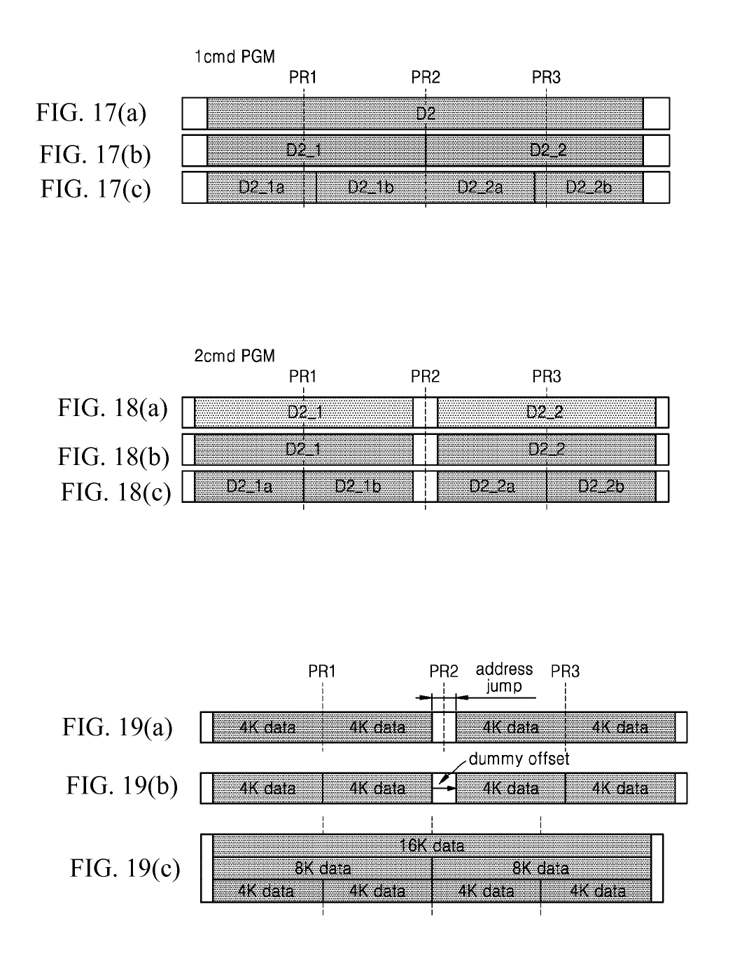

FIG. 17 illustrates page layouts showing a partial read operation for data having two different sizes with an address padding approach consistent with certain embodiments of the inventive concept.

If a dummy padding approach is applied to a page to define a left padding region and a right padding region having the same size at both ends of the page and a program operation is executed to store data D2 in the page, as illustrated in FIG. 17(a), a first half of the data D2 may be loaded into a left section of the page and a second half of the data D2 may be loaded into a right section of the page. The left section and the right section of the page may be divided by a partial read reference boundary PR2 located at a central region of the page. If the page has a memory size of 16 Kbytes, 8 Kbyte data D2_1 may be loaded in the left section of the page and the remaining 8 Kbyte data D2_2 may be loaded in the right section of the page.

Accordingly, as illustrated in FIG. 17(b), the memory device 100 may support a partial read function that partially reads out data having a half size of the page using the partial read reference boundary PR.

Referring to FIG. 17(c), three partial read reference boundaries PR1, PR2 and PR3 equally dividing a total region of the page including the padding regions into four regions are inconsistent with three boundaries between four data D2_1a, D2_1b, D2_2a and D2_2b having the same size. To this end, the memory device 100 cannot support a partial read function that partially reads out data having a size corresponding to one quarter of the page.

As a result, data having at least two different sizes cannot be partially read out using only the dummy padding approach.

FIG. 18 illustrates page layouts showing a partial read operation of data having two different sizes with an address padding approach and execution of two commands according to certain embodiments of the inventive concept.

If data are loaded into page buffers with executions of two commands to provide a page layout of FIG. 18(a), a partial read operation of data having a half size of the page and a partial read operation of data having a quarter size of the page can be successfully executed. (See, e.g., FIGS. 18(b) and 18(c)). Here, the legend “2cmd PGM” shown in FIG. 18 (a) denotes a program operation performed by execution of two commands.

In the embodiment illustrated in FIG. 18, the command may be executed twice to load the data into the page buffer circuit 120. Thus, a certain degree of excessive program overhead may occur.

FIG. 19 illustrates page layouts showing a partial read operation of data having two different sizes with address jumping according to embodiments of the inventive concept. FIG. 19(a) illustrates a page layout including programmed memory cells. FIG. 19(b) illustrates a page layout including page buffers, and FIG. 19(c) illustrates a page layout of data received by or provided from the memory device.

As illustrated in FIGS. 19(a) and 19(b), a dummy column address section (i.e., a dummy offset section) may be set in a central position of the page such that a partial read operation of data having a half size of the page and a partial read operation of data having a quarter size of the page can be successfully executed.

Referring back to FIG. 2, if a first-type write command and a column address are received by the memory device 100, the control logic unit 150 will generate the first decoder control signal CTRL_DEC1. The column address provided by the memory controller 200 together with the first-type write command may be a start column address next to a left padding region in the page. Thus, the left padding region may be set in a left end of the page using the column address received by the memory device 100 together with the first-type write command.

The column decoder 142 may generate the column selection signal SEL_COL for sequentially assigning the page buffers in the page from the page buffer corresponding to the column address based on the first decoder control signal CTRL_DEC1 until the dummy column address section (i.e., the dummy offset section) is detected. If the dummy column address section (i.e., the dummy offset section) is detected, the column selection signal SEL_COL generated from the column decoder 142 may execute an operation that jumps the page buffers corresponding to the bit lines included in the dummy column address section (i.e., the dummy offset section).

Accordingly, the 16 Kbyte data of the page layout illustrated in FIG. 19(c) may be equally divided into a first 8 Kbyte data and a second 8 Kbyte data, and the first and second 8 Kbyte data may be separately loaded into two regions of the page buffer circuit 120 which are separated by a partial read reference boundary PR2, as illustrated in FIG. 19(b). Memory cells connected to a word line selected by the row selection signal generated from the row decoder 141 may be programmed to provide the page layout of FIG. 19(a).

As described above, the column decoder 142 may execute an address jump operation of a dummy column address section (i.e., a dummy offset section) to decode the column address. As a result, the partial read reference boundaries PR1 and PR3 may be consistent with a first boundary between the first quarter data and the second quarter data and a second boundary between the third quarter data and the fourth quarter data, as illustrated in FIG. 19(a) and FIG. 9(b). Thus, the memory device 100 may support a partial read function that partially reads data having a quarter size of the page.

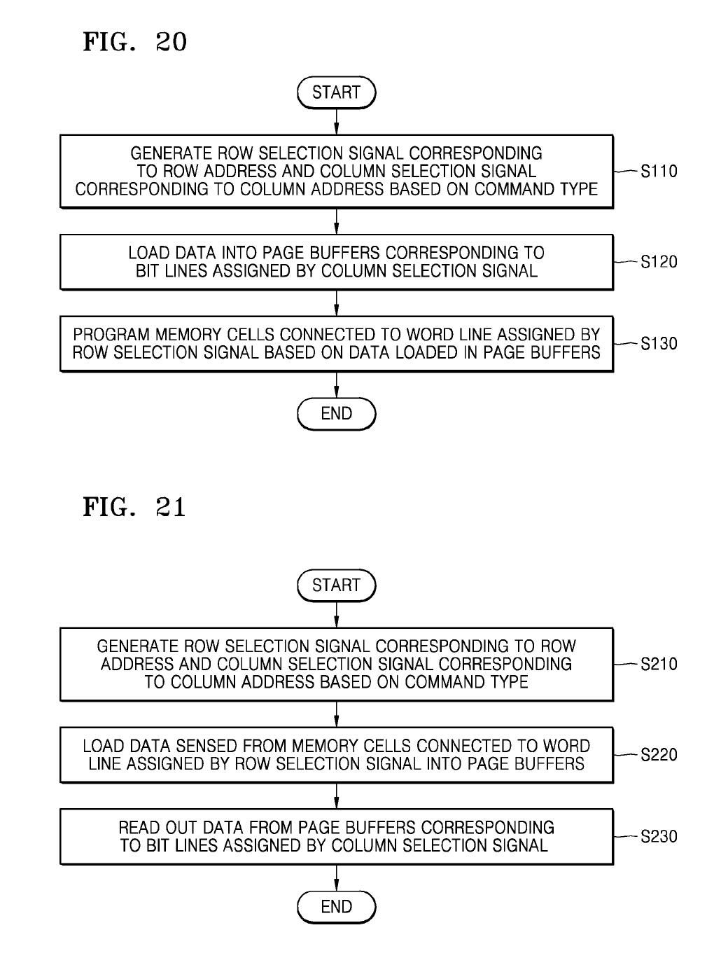

A program operation of the memory device 100 according to embodiments will now be described with reference to FIG. 20.

FIG. 20 is a flowchart summarizing a method of programming the memory device 100 shown in FIGS. 1 and 2. The program method illustrated in FIG. 20 may be applied to various nonvolatile memory devices.

First, the address decoder 140 of the memory device 100 may execute an operation that generates a row selection signal and a column selection signal in response to a row address and a column address provided from the memory controller 200 (S110).

If a first-type write command is received by the memory device 100, the column decoder 142 will generate a column selection signal for jumping page buffers corresponding to bit lines included in a dummy column address section. Specifically, if the first-type write command is received by the memory device 100, the column selection signal generated from the column decoder 142 may execute a jump operation that jumps a start column address of the initial set dummy column address section into a column address next to an end column address of the initial set dummy column address section and a non-jump operation that sequentially assigns page buffers in a section other than the initial set dummy column address section based on a size of data to be loaded.

However, if a second-type write command is received by the memory device 100, the column decoder 142 will generate a column selection signal jumping page buffers corresponding to bit lines included in section(s) other than the dummy column address section. That is, if the second-type write command is received by the memory device 100, the page buffers corresponding to the bit lines included in the dummy column address section may be sequentially assigned by the column selection signal generated from the column decoder 142.

And, if a third-type write command is received by the memory device 100, the column decoder 142 will generate a column selection signal sequentially assigning all of the page buffers included in a selected page without jumping of the initial set dummy column address section.

Next, the data I/O circuit 130 of the memory device 100 may execute an operation that loads the data provided from the memory controller 200 into the page buffers of the page buffer circuit 120 corresponding to the bit lines assigned by the column selection signal (S120).

Thus, the page buffers included in the dummy column address section of the page buffer circuit 120 may be jumped by the column selection signal generated based on the first-type write command. Thus, the data D1 received by the memory device 100 as illustrated in FIG. 10(b) may be loaded into the page buffers to provide the page layout of FIG. 10(a).

Alternately, the page buffers included in a section other than the dummy column address section of the page buffer circuit 120 may be jumped by the column selection signal generated based on the second-type write command. Thus, the data S1 received by the memory device 100 as illustrated in FIG. 11(b) may be loaded into the page buffers to provide the page layout of FIG. 11(a).

Still again, all of the page buffers corresponding to the bit lines of the page buffer circuit 120 may be sequentially assigned by the column selection signal generated based on the third-type write command without address jumping. Thus, the data D1 received by the memory device 100 as illustrated in FIG. 12(b) may be loaded into the page buffers to provide the page layout of FIG. 12(a).

Subsequently, the memory device 100 may execute a program operation that stores the data loaded into the page buffers of the page buffer circuit 120 into memory cells connected to a word line selected by the row selection signal (S130).

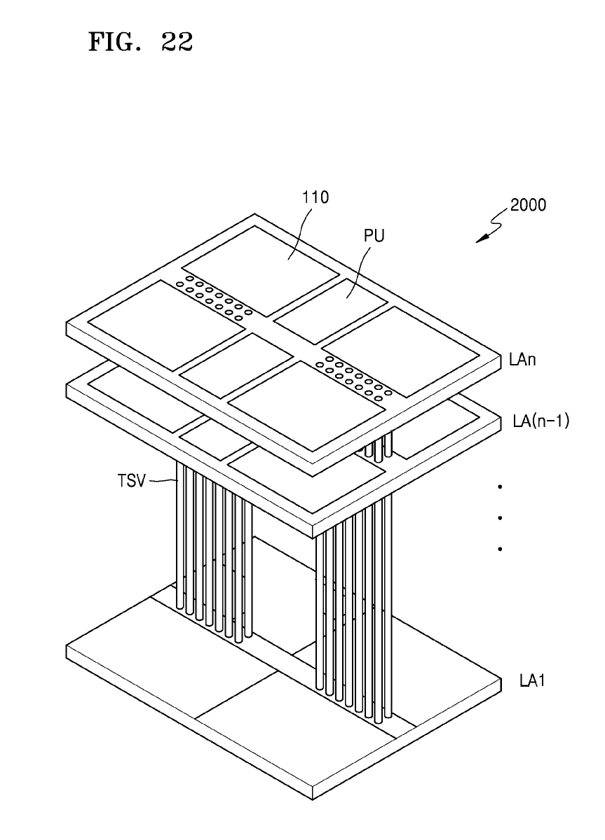

A read operation executed by the memory device 100 of FIGS. 1 and 2 according to embodiments of the inventive concept will now be described with reference to FIG. 21.

FIG. 21 is a flowchart summarizing a method of reading data stored in the memory device 100 shown in FIGS. 1 and 2. The read method illustrated in FIG. 21 may be applied to various nonvolatile memory devices.

First, the address decoder 140 of the memory device 100 may execute an operation that generates a row selection signal and a column selection signal in response to a row address and a column address provided by the memory controller 200 (S210).

If a first-type read command is received by the memory device 100, the column decoder 142 will generate a column selection signal for jumping page buffers corresponding to bit lines included in a dummy column address section. Specifically, if the first-type read command is received by the memory device 100, the column selection signal generated from the column decoder 142 may execute a jump operation that jumps a start column address of the initial set dummy column address section into a column address next to an end column address of the initial set dummy column address section and a non-jump operation that sequentially assigns page buffers in a section other than the initial set dummy column address section based on a size of read data.

If a second-type read command is received by the memory device 100, the column decoder 142 will generate a column selection signal for jumping page buffers corresponding to bit lines included in a section other than the dummy column address section. That is, if the second-type read command is received by the memory device 100, the page buffers corresponding to the bit lines included in a section other than the dummy column address section may be sequentially assigned by the column selection signal generated from the column decoder 142.

And, if a third-type read command is received by the memory device 100, the column decoder 142 will generate a column selection signal for sequentially assigning all of the page buffers included in a selected page without jumping of the initial set dummy column address section.

Next, the memory device 100 may execute an operation that loads the data stored in memory cells connected to a word line selected by the row selection signal into the page buffers of the page buffer circuit 120 assigned by the column selection signal (S220).

Subsequently, the data I/O circuit 130 of the memory device 100 may execute a read operation that reads out the data loaded into the page buffers of the page buffer circuit 120 corresponding to the bit lines assigned by the column selection signal (S230).

This, the page buffers included in the dummy column address section of the page buffer circuit 120 may be jumped by the column selection signal generated based on the first-type read command. Thus, the data D1_1, D1_2, D1_3 and D1_4 loaded in the page buffers as illustrated in FIG. 13(a) may be read to provide the page layout of FIG. 13(b), and may thereafter be communicated to the memory controller 200. Or the page buffers included in a section other than the dummy column address section of the page buffer circuit 120 may be jumped by the column selection signal generated based on the second-type read command. Thus, the data S1_1, S1_2 and S1_3 loaded in the page buffers as illustrated in FIG. 14(a) may be read to provide the page layout of FIG. 14(b), and may thereafter be communicated to the memory controller 200. Or still again, all of the page buffers corresponding to the bit lines of the page buffer circuit 120 may be sequentially assigned by the column selection signal generated based on the third-type read command without address jumping. Thus, the data D1_1, S1_1, D1_2, S1_2, D1_3, S1_3 and D1_4 loaded in the page buffers as illustrated in FIG. 15(a) may be read to provide the page layout of FIG. 15(b), and may thereafter be communicated to the memory controller 200.

FIG. 22 is a perspective view illustrating a memory device 2000 according to certain embodiments of the inventive concept.

As illustrated in FIG. 22, the memory device 2000 comprises a plurality of stacked semiconductor layers LA1 through LAn. Each of the semiconductor layers may correspond to a chip including the memory device 100 shown in FIG. 1 or 2. Alternatively, at least one of the semiconductor layers may be a master chip interfacing with an external memory controller, and each of remaining semiconductor layers may respectively be a slave chip including the memory cell array portion 110 of FIG. 2. In the embodiment shown in FIG. 22, a bottommost layer LA1 (i.e., a first semiconductor layer) may be the master chip and the remaining layers LA2 through LAn may be slave chips.

Various control, command and addressed signals may be communicated across the stacked plurality of semiconductor layers using a number of silicon vias (TSVs). The first semiconductor layer LA1 may be used to communicate with an external memory controller via external conductive members (not shown). One configuration and operation approach for the memory device 2000 will now be described assuming that the first semiconductor layer LA1 is a master chip and the remaining semiconductor layer LA2 through LAn are slave chips.

Thus, the first semiconductor layer LA1 may be used to drive the memory cell array portions 110 included in the slave chips. The first semiconductor layer LA1 may include a logic circuit that receives data, addresses and commands supplied from an external memory controller to transmit the data, the addresses and the commands to the slave chips. The logic circuit of the first semiconductor layer LA1 may also receive data provided from the slave chips to transmit the data to the external memory controller. Each semiconductor layer, for example, N^{th} semiconductor layer LAn may include a memory cell array portion 110 and a peripheral circuit PU for driving the memory cell array portion 110. The memory cell array portion 110 included in each slave chip may correspond to the memory cell array portion 110 of FIG. 2, and the peripheral circuit PU of each slave chip may include the page buffer circuit 120, the data I/O circuit 130, the address decoder 140 and the control logic unit 150 illustrated in FIG. 2.

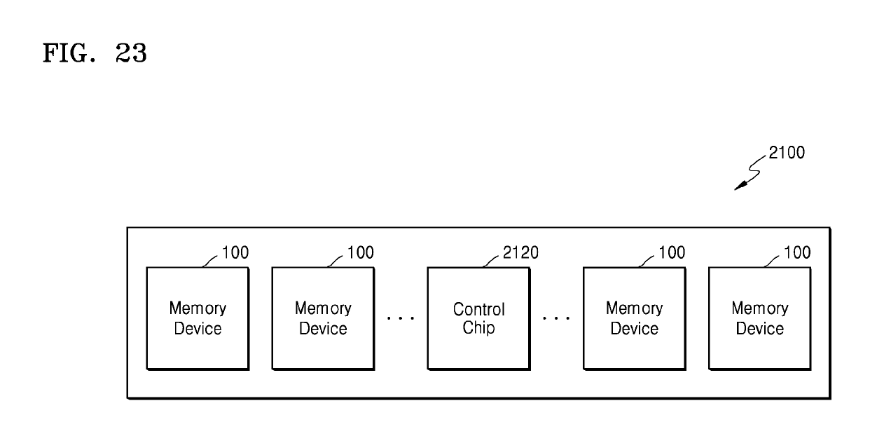

FIG. 23 is a block diagram illustrating a memory module 2100 according to certain embodiments of the inventive concept.

Referring to FIG. 23, the memory module 2100 comprises a plurality of memory devices 100 (i.e., a plurality of memory chips) and a control chip 2120. Each of the memory chips 100 may store data therein. For example, each of the memory chips 100 may be the memory device 100 shown in FIG. 1 or 2. The control chip 2120 may control an operation of the memory chips 100 in response to various signals generated and provided from an external memory controller. For example, the control chip 2120 may activate at least one of the memory chips 100, which is selected by a chip selection signal supplied from an external device. Moreover, the control chip 2120 may execute an error check and correction operation of data which are read out of each memory chip 100.

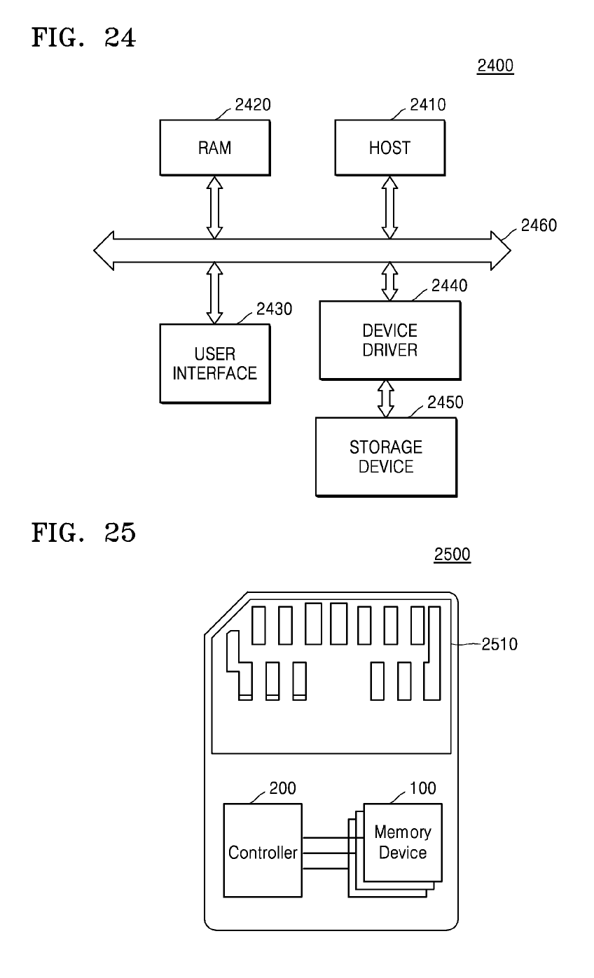

FIG. 24 is a block diagram illustrating a computing system 2400 including a nonvolatile memory system according to embodiments of the inventive concept.

Referring to FIG. 24, the computing system 2400 may be a mobile system or a desktop computer comprising a host 2410 having a central processing unit (CPU), a random access memory (RAM) 2420, a user interface 2430 and a device driver 2440 that communicate with each other through a bus 2460. The computing system 2400 may further include a nonvolatile storage device 2450 which is connected to the device driver 2440. The host 2410 may control overall operations of the computing system 2400 and may execute logical operations corresponding to user's commands inputted though the user interface 2430 or may process data inputted though the user interface 2430. The RAM 2420 may function as a data memory of the host 2410, and the host 2410 may write user's data in the nonvolatile storage device 2450 through the device driver 2440 or may read out the data stored in the nonvolatile storage device 2450 through the device driver 2440. Although FIG. 24 illustrates an example in which the device driver 2440 for controlling the nonvolatile storage device 2450 is physically separated from the host 2410, but the inventive concept is not limited thereto. That is, the device driver 2440 may be included in the host 2410. The nonvolatile storage device 2450 may include the memory device 100 shown in FIG. 1.

FIG. 25 is a schematic view illustrating a memory card 2500 according to certain embodiments of the inventive concept. The memory card 2500 may be used as a portable storage medium which can be connected to an electronic system such as a mobile system or a desktop computer. As illustrated in FIG. 25, the memory card 2500 may include memory devices 100, a memory controller 200 and a port region 2510. The memory card 2500 may communicate with an external host (not shown) through the port region 2510, and the memory controller 200 may control the memory devices 100.

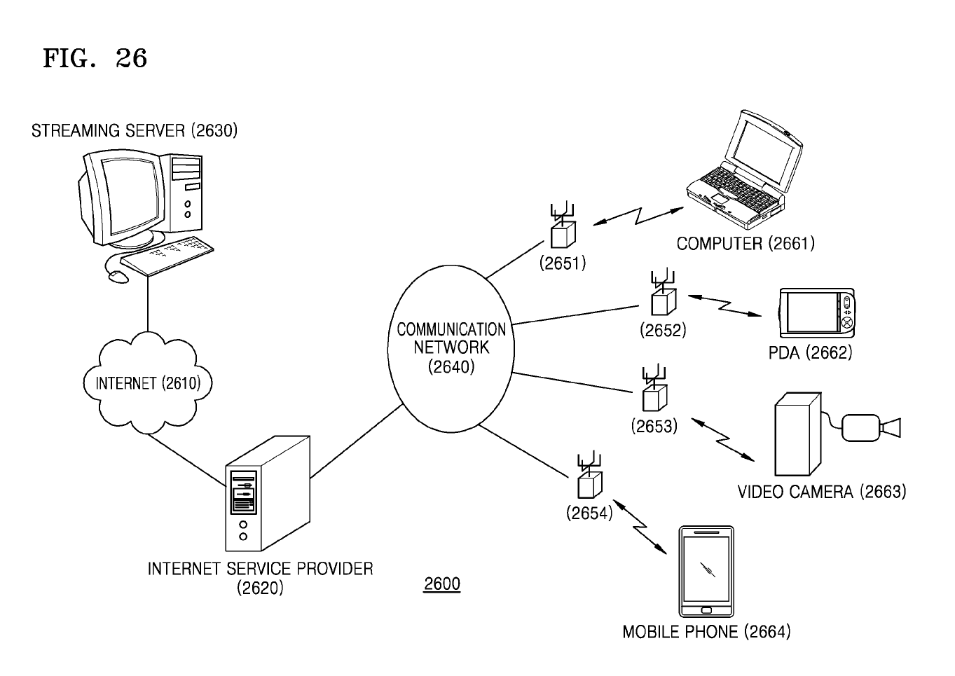

FIG. 26 is a schematic view illustrating a system 2600 of transmitting and receiving contents including a memory device according to some embodiments of the inventive concept.

The system 2600 may include a plurality of independent and separate devices. For example, independent devices such as a computer 2661, a personal digital assistant (PDA) 2662, a camera 2663 and a mobile phone 2664 may be connected to an internet 2610 through an internet service provider 2620, a communication network 2640 and wireless base stations 2651˜2654. The memory system according to the embodiments may be included in each of the independent devices 2661, 2662, 2663 and 2664 of the system 2600. For example, each of the computer 2661, the PDA 2662, the camera 2663 and the mobile phone 2664 may include the memory device 100 shown in FIG. 1 or 2.

The system 2600 is not limited to the embodiment illustrated in FIG. 26. For example, the independent devices 2661, 2662, 2663 and 2664 may be directly connected to the communication network 2640 without use of the wireless base stations 2651, 2652, 2653 and 2654. The camera 2663 may be a digital video camera which is capable of taking video images. The mobile phone 2664 may employ at least one of various protocols such as a personal digital communications (PDC) technique, a code division multiple access (CDMA) technique, a wideband code division multiple access (W-CDMA) technique, a global system for mobile communications (GSM) technique and a personal handy phone system (PHS) technique.

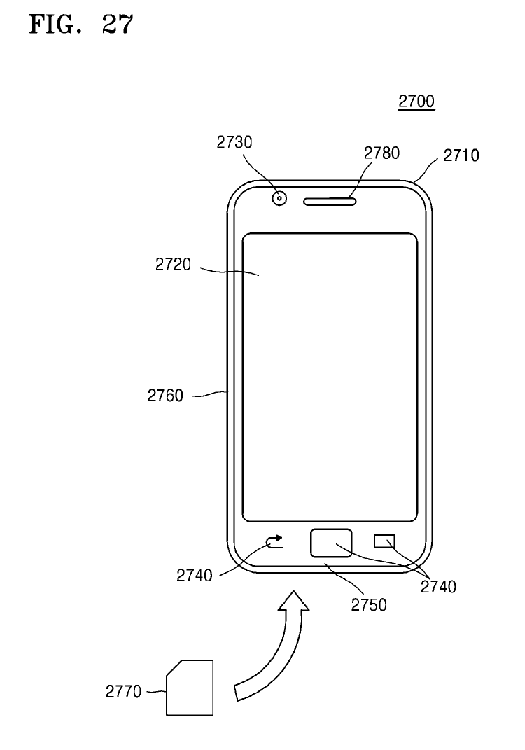

FIG. 27 is a mobile terminal 2700 including a memory system according to certain embodiments of the inventive concept.

The mobile terminal 2700 may correspond to the mobile phone 2664 shown in FIG. 26 and may include the memory device 100 shown in FIG. 1 or FIG. 2. The mobile terminal 2700 may have an unlimited function. That is, the function of the mobile terminal 2700 may be extendable or changeable using various application programs. The mobile terminal 2700 may include an internal antenna 2710 for exchanging radio frequency (RF) signals with wireless base stations. The mobile terminal 2700 may further include a display unit 2720 such as a liquid crystal display (LCD) unit or an organic light emitting diode (OLED) display unit. The display unit 2720 may display video images which are captured by a camera 2730 or video images which are received through the internal antenna 2710 and decoded by an image processor. The mobile terminal 2700 may further include operation panels 2740 having a control button and touch panels. If the display unit 2720 is a touch screen, the operation panels 2740 may further include a touch sense panel of the display unit 2720. The mobile terminal 2700 may further include a speaker 2780 and a microphone 2750. In addition, the mobile terminal 2700 may include the camera 2730. Moreover, the mobile terminal 2700 may be configured to include a storage medium 2770 for storing video images or still pictures which are captured by the camera 2730 or received through e-mails. The mobile terminal 2700 may further include a slot 2760 for connecting the storage medium 2770 thereto. The storage medium 2770 may realized to include the memory device 100 shown in FIG. 1 or 2.

While the inventive concept has been particularly shown and described with reference to exemplary embodiments thereof, it will be understood that various changes in form and details may be made therein without departing from the scope of the following claims.

What is claimed is:

1. A method of programming a memory device, the method comprising:
generating a row selection signal corresponding to a row address and a column selection signal corresponding to a column address in a memory cell array portion based on a command type received by the memory device;
loading data into page buffers corresponding to bit lines assigned by the column selection signal; and
programming memory cells connected to a word line assigned by the row selection signal based on the data loaded into the page buffers,
wherein the column selection signal is generated to selectively jump a portion of the page buffers according to the command type.

2. The method of claim 1, wherein if the command type is a first-type write command, the column selection signal is generated to selectively jump page buffers corresponding to bit lines included in a dummy column address section.

3. The method of claim 2, wherein the column selection signal executes a jump operation that jumps a start column address of the initial set dummy column address section to a column address next to an end column address of the initial set dummy column address section, and a non-jump operation that sequentially assigns page buffers corresponding to bit lines included in a section other than the initial set dummy column address section based on a size of data to be loaded into the page buffers.

4. The method of claim 1, wherein if the command type is a second-type write command, the column selection signal is generated to selectively jump page buffers corresponding to bit lines included in a section other than a dummy column address section.

5. The method of claim 1, wherein if the command type is a third-type write command, the column selection signal is generated to sequentially allocate all of page buffers corresponding to bit lines included in a page selected by the row selection signal and the column selection signal without page buffer jumping.

6. The method of claim 1, wherein a page selected by the row selection signal includes a dummy column address section and the dummy column address section is disposed at a central position of the selected page to divide the selected page into a left section and a right section having the same size.

7. The method of claim 1, wherein a page selected by the row selection signal includes a dummy column address section and the dummy column address section is set to support a partial read operation of data having at least two different sizes in the selected page.

8. The method of claim 7, wherein a size of data read by the partial read operation is at least a quarter of a size of the selected page.

9. The method of claim 1, wherein a page selected by the row selection signal includes a dummy column address section and the dummy column address section is allocated as an area at least one of store security information and error check information.

10. The method of claim 1, wherein the memory cell array portion comprises at least a portion of a two-dimensional flash memory cell array structure, or a three-dimensional flash memory cell array structure.

11. A method of reading a memory device, the method comprising:
generating a row selection signal corresponding to a row address and a column selection signal corresponding to a column address in a memory cell array portion based on a type of a command received from a memory controller;
loading data stored in memory cells of the memory array portion connected to a word line assigned by the row selection signal to page buffers; and
reading the data loaded to the page buffers corresponding to bit lines assigned by the column selection signal,
wherein the column selection signal is generated to selectively jump a portion of the page buffers according to a command type.

12. The method of claim 11, wherein if the command type is a first-type read command, the column selection signal is generated to selectively jump page buffers corresponding to bit lines included in a dummy column address section.

13. The method of claim 12, wherein the column selection signal executes a jump operation that jumps a start column address of the initial set dummy column address section into a column address next to an end column address of the initial set dummy column address section and a non-jump operation that sequentially assigns page buffers corresponding to bit lines included in a section other than the dummy column address section based on a size of data to be read.

14. The method of claim 11, wherein if the command type is a second-type read command, the column selection signal is generated to selectively jump page buffers corresponding to bit lines included in a section other than a dummy column address section.

15. The method of claim 11, wherein if the command type is a third-type read command, the column selection signal is generated to sequentially allocate all of page buffers corresponding to bit lines included in a page selected by the row selection signal and the column selection signal without page buffer jumping.

16. A memory device receiving a command of various type from a memory controller, the memory device comprising:
a memory cell array portion; and
a column decoder that receives a column address and generates a corresponding column selection signal in response to the command type, wherein the column selection signal is during read/write operation to select page buffers corresponding to bit lines, and
if the command type is a first-type command, the column decoder generates a column selection signal that enables jumping of page buffers corresponding to bit lines included in a dummy column address section of the memory cell array portion.

17. The memory device of claim 16, wherein if the command type is a second-type command, the column decoder generates a column selection signal that enables jumping page buffers corresponding to bit lines included in a section of the memory cell array portion other than the dummy column address section.

18. The memory device of claim 17, wherein if the command type is a third-type command, the column decoder generates a column selection signal that enables successive allocation of page buffers corresponding to bit lines included in the dummy column address section without page buffer jumping.

19. The memory device of claim 18, wherein the memory device further comprises a control logic unit and the column decoder comprises:
an address jump processor that receives a column address and generates an address jump signal based on one of a first decoder control signal, a second decoder control signal, and a third decoder control signal and dummy column address section information provided by the control logic unit; and
a column selection signal generator that generates the column selection signal.

20. The memory device of claim 18, wherein upon receiving the first decoder control signal, the address jump processor generates a first address jump signal instructing the column selection signal generator to generate the column selection signal that enables jumping of page buffers corresponding to bit lines included in the dummy column address section,
upon receiving the second decoder control signal, the address jump processor generates a second address jump signal instructing the column selection signal generator to generate the column selection signal that enables successive allocation of page buffers corresponding to bit lines included in the dummy column address section without page buffer jumping, and
upon receiving the third decoder control signal, the address jump processor generates a third address jump signal instructing the column selection signal generator to generate the column selection signal that enables successive allocation of page buffers corresponding to bit lines included in the dummy column address section without page buffer jumping.
